(19) United States
(12) Patent Application Publication
(10) Pub. No.: US 2025/0318174 A1
(43) Pub. Date: Oct. 9, 2025

(54) TRANSISTOR CONTACT STRUCTURE WITH UPPER LEVEL INSULATING SPACER AND METHOD OF MAKING THE SAME

(71) Applicant: SANDISK TECHNOLOGIES LLC, Addison, TX (US)

(72) Inventors: Takahito FUJITA, Yokkaichi (JP); Kiyokazu SHISHIDO, Yokkaichi (JP); Hiroshi NAKATSUJI, Yokkaichi (JP)

(21) Appl. No.: 18/628,059

(22) Filed: Apr. 5, 2024

(51) Int. Cl. H01L 29/78; H01L 29/06; H01L 29/66

(52) U.S. Cl. CPC H10D 30/611; H10D 62/10; H10D 64/021

(57) ABSTRACT

A device structure includes a semiconductor device containing at least one electrical node, a contact-level dielectric layer overlying the semiconductor device, a contact via structure vertically extending through a lower portion of the contact-level dielectric layer and contacting one of the at least one electrical node, a metal line structure laterally extending along a first horizontal direction and embedded within an upper portion of the contact-level dielectric layer, the metal line structure including a horizontally-extending metal line portion and a downward-protruding pillar portion that protrudes downward below a bottom surface of the horizontally-extending metal line portion and contacts a first segment of a top surface of the contact via structure, and an insulating spacer which contacts a sidewall of the downward-protruding pillar portion and second segment of the top surface of the contact via structure.

### FIELD

The present disclosure relates generally to the field of semiconductor devices and specifically to transistor contact structures with self-aligned upper-contact-level insulating spacers and methods of making the same.

### BACKGROUND

High density metal wiring in semiconductor circuits suffers from time-dependent dielectric breakdown (TDDB), which refers to breakdown of electrical isolation between adjacent metal vias or interconnects during prolonged device operation, i.e., due to flow of electrical current in adjacent metal vias or interconnects.

### SUMMARY

According to an aspect of the present disclosure, a device structure includes a semiconductor device containing at least one electrical node, a contact-level dielectric layer overlying the semiconductor device, a contact via structure vertically extending through a lower portion of the contact-level dielectric layer and contacting one of the at least one electrical node, a metal line structure laterally extending along a first horizontal direction and embedded within an upper portion of the contact-level dielectric layer, the metal line structure including a horizontally-extending metal line portion and a downward-protruding pillar portion that protrudes downward below a bottom surface of the horizontally-extending metal line portion and contacts a first segment of a top surface of the contact via structure, and an insulating spacer which contacts a sidewall of the downward-protruding pillar portion and second segment of the top surface of the contact via structure.

According to another aspect of the present disclosure, a method of forming a device structure comprises: forming a semiconductor device comprising an electrical node; forming a contact-level dielectric layer over the semiconductor device; forming a contact via structure vertically extending through the contact-level dielectric layer and contacting the electrical node; vertically recessing an upper portion of the contact via structure, wherein a recessed top surface of the contact via structure is formed within a first horizontal plane, and a recess cavity is formed above the contact via structure; forming an insulating spacer in a peripheral portion of the recess cavity; forming a line cavity in an upper portion of the contact-level dielectric layer by forming a patterned etch mask layer over the contact-level dielectric layer and by performing an anisotropic etch process, wherein a portion of the recess cavity that is not filled within the insulating spacer is incorporated into the line cavity; and forming a metal line structure in the line cavity directly on the recessed top surface of the contact via structure.

### BRIEF DESCRIPTION OF THE DRAWINGS

FIG. 1A is a vertical cross-sectional view of an exemplary structure after formation of a gate stack structure according to an embodiment of the present disclosure.

FIG. 1B is a top-down view of the exemplary structure of FIG. 1A. The vertical plane A-A′ is the cut plane of the vertical cross-sectional view of FIG. 1A. FIG. 1C is a vertical cross-sectional view of the exemplary structure along the vertical plane C-C′ of FIG. 1B.

FIG. 2A is a vertical cross-sectional view of an exemplary structure after formation of source/drain extension regions according to an embodiment of the present disclosure. FIG. 2B is a top-down view of the exemplary structure of FIG. 2A. The vertical plane A-A′ is the cut plane of the vertical cross-sectional view of FIG. 2A. FIG. 2C is a vertical cross-sectional view of the exemplary structure along the vertical plane C-C′ of FIG. 2B.

FIG. 3A is a vertical cross-sectional view of an exemplary structure after formation of a gate spacer and source/drain regions according to an embodiment of the present disclosure. FIG. 3B is a top-down view of the exemplary structure of FIG. 3A. The vertical plane A-A′ is the cut plane of the vertical cross-sectional view of FIG. 3A. FIG. 3C is a vertical cross-sectional view of the exemplary structure along the vertical plane C-C′ of FIG. 3B.

FIG. 4A is a vertical cross-sectional view of an exemplary structure after formation of dielectric liners and a contact-level dielectric layer according to an embodiment of the present disclosure. FIG. 4B is a top-down view of the exemplary structure of FIG. 4A. The vertical plane A-A′ is the cut plane of the vertical cross-sectional view of FIG. 4A. FIG. 4C is a vertical cross-sectional view of the exemplary structure along the vertical plane C-C′ of FIG. 4B.

FIG. 5A is a vertical cross-sectional view of an exemplary structure after formation of contact via cavities according to an embodiment of the present disclosure. FIG. 5B is a top-down view of the exemplary structure of FIG. 5A. The vertical plane A-A′ is the cut plane of the vertical cross-sectional view of FIG. 5A. FIG. 5C is a vertical cross-sectional view of the exemplary structure along the vertical plane C-C′ of FIG. 5B.

FIG. 6A is a vertical cross-sectional view of an exemplary structure after formation of metal-semiconductor alloy regions according to an embodiment of the present disclosure. FIG. 6B is a top-down view of the exemplary structure of FIG. 6A. The vertical plane A-A′ is the cut plane of the vertical cross-sectional view of FIG. 6A. FIG. 6C is a vertical cross-sectional view of the exemplary structure along the vertical plane C-C′ of FIG. 6B.

FIG. 7A is a vertical cross-sectional view of an exemplary structure after formation of contact via structures according to an embodiment of the present disclosure. FIG. 7B is a top-down view of the exemplary structure of FIG. 7A. The vertical plane A-A′ is the cut plane of the vertical cross-sectional view of FIG. 7A. FIG. 7C is a vertical cross-sectional view of the exemplary structure along the vertical plane C-C′ of FIG. 7B.

FIG. 8A is a vertical cross-sectional view of an exemplary structure after vertically recessing the contact via structures according to an embodiment of the present disclosure. FIG. 8B is a top-down view of the exemplary structure of FIG. 8A. The vertical plane A-A′ is the cut plane of the vertical cross-sectional view of FIG. 8A. FIG. 8C is a vertical cross-sectional view of the exemplary structure along the vertical plane C-C′ of FIG. 8B.

FIG. 9A is a vertical cross-sectional view of an exemplary structure after formation of an insulating spacer material layer according to an embodiment of the present disclosure. FIG. 9B is a top-down view of the exemplary structure of FIG. 9A. The vertical plane A-A′ is the cut plane of the vertical cross-sectional view of FIG. 9A. FIG. 9C is a vertical cross-sectional view of the exemplary structure along the vertical plane C-C′ of FIG. 9B.

FIG. 10A is a vertical cross-sectional view of an exemplary structure after formation of insulating spacers according to an embodiment of the present disclosure. FIG. 10B is a top-down view of the exemplary structure of FIG. 10A. The vertical plane A-A′ is the cut plane of the vertical cross-sectional view of FIG. 10A. FIG. 10C is a vertical cross-sectional view of the exemplary structure along the vertical plane C-C′ of FIG. 10B.

FIG. 11A is a vertical cross-sectional view of an exemplary structure after formation of line cavities according to an embodiment of the present disclosure. FIG. 11B is a top-down view of the exemplary structure of FIG. 11A. The vertical plane A-A′ is the cut plane of the vertical cross-sectional view of FIG. 11A. FIG. 11C is a vertical cross-sectional view of the exemplary structure along the vertical plane C-C′ of FIG. 11B.

FIG. 12A is a vertical cross-sectional view of an exemplary structure after formation of metal line structures according to an embodiment of the present disclosure. FIG. 12B is a top-down view of the exemplary structure of FIG. 12A. The vertical plane A-A′ is the cut plane of the vertical cross-sectional view of FIG. 12A. FIG. 12C is a vertical cross-sectional view of the exemplary structure along the vertical plane C-C′ of FIG. 12B. FIG. 12D is a vertical cross-sectional view of the exemplary structure along the vertical plane D-D′ of FIG. 12B. FIG. 12E is a vertical cross-sectional view of the exemplary structure along the vertical plane E-E′ of FIG. 12B.

### DETAILED DESCRIPTION

As discussed above, embodiments of the present disclosure are directed to contact structures with self-aligned upper-contact-level insulating spacers and methods of making the same.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, there above, and/or there below.

As used herein, a “layer stack” refers to a stack of layers. As used herein, a “line” or a “line structure” refers to a layer that has a predominant direction of extension, i.e., having a direction along which the layer extends the most.

As used herein, a “semiconducting material” refers to a material having electrical conductivity in the range from 1.0×10⁻⁶ S/cm to 1.0×10⁵ S/cm. As used herein, a “semiconductor material” refers to a material having electrical conductivity in the range from 1.0×10⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/cm. As used herein, an “insulator material”, “insulating material” or a “dielectric material” refers to a material having electrical conductivity less than 1.0×10⁻⁶ S/cm. As used herein, a “heavily doped semiconductor material” refers to a semiconductor material that is doped with electrical dopant at a sufficiently high atomic concentration to become a conductive material, i.e., to have electrical conductivity greater than 1.0×10⁵ S/cm. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁶ S/cm to 1.0×10⁵ S/cm. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material can be semiconducting or conductive depending on the atomic concentration of electrical dopants therein. As used herein, a “metallic material” refers to a conductive material including at least one metallic element therein. All measurements for electrical conductivities are made at the standard condition.

As used herein, a “field effect transistor” refers to any semiconductor device having a semiconductor channel through which electrical current flows with a current density modulated by an external electrical field. As used herein, a “channel region” refers to a semiconductor region in which mobility of charge carriers is affected by an applied electrical field. A “gate electrode” refers to a conductive material portion that controls electron mobility in the channel region by application of an electrical field. A “source region” refers to a doped semiconductor region that supplies charge carriers that flow through the channel region. A “drain region” refers to a doped semiconductor region that receives charge carriers supplied by the source region and passes through the channel region. A “source/drain region” refers to a doped semiconductor region that may function as a source region or a drain region. An “active region” refers to a combination of a source region, a drain region, and a channel region of a field effect transistor. A “source extension region” refers to a doped semiconductor region having a lesser dopant concentration than, and having a same type of doping as, a source region and including a portion disposed between the source region and the channel region. A “drain extension region” refers to a doped semiconductor region having a lesser dopant concentration than, and having a same type of doping as, a drain region and including a portion disposed between the drain region and the channel region.

Embodiments of the present disclosure are directed to metal interconnect structures configured for reducing electrical shorts and time-dependent dielectric breakdown between adjacent conductive lines or vias. A contact via structure is formed through a contact-level dielectric layer on an electrical node of a semiconductor device. The top surface of the contact via structure is vertically recessed to form a recess cavity. An insulating spacer is formed by depositing an insulating spacer material layer and by performing an anisotropic etch process. The insulating spacer is shorter than the contact via structure. Therefore, the insulating spacer is relatively easy to form without the need to reach a deep bottom end of the contact via cavity in a high aspect ratio contact via opening or forming the insulating spacer in a relatively narrow bottom portion of the contact via opening. A line cavity is formed in an upper portion of the contact-level dielectric layer such that the line cavity incorporates a volume of the recess cavity that is not filled with the insulating spacer. A metal line structure is formed in the line cavity. The metal line structure overlies the contact via structure and comprises a downward-protruding pillar portion that is self-aligned to a center segment of a top surface of the contact via structure. An insulating spacer at least partially laterally surrounds the downward-protruding pillar portion. The lateral extent of the downward-protruding pillar portion is limited due to the presence of the insulating spacer. The insulating spacer is located at the vertical level of the relatively shallow horizontally-extending portions of the metal line structures. Thus, electrical short circuits and time-dependent dielectric breakdown between adjacent lines can be reduced or avoided due to the presence of the insulating spacer without extending the insulating spacer to the bottom of the contact via structure below the level of the metal line structures. The various embodiments of the present disclosure are now described in detail with reference to accompanying drawings.

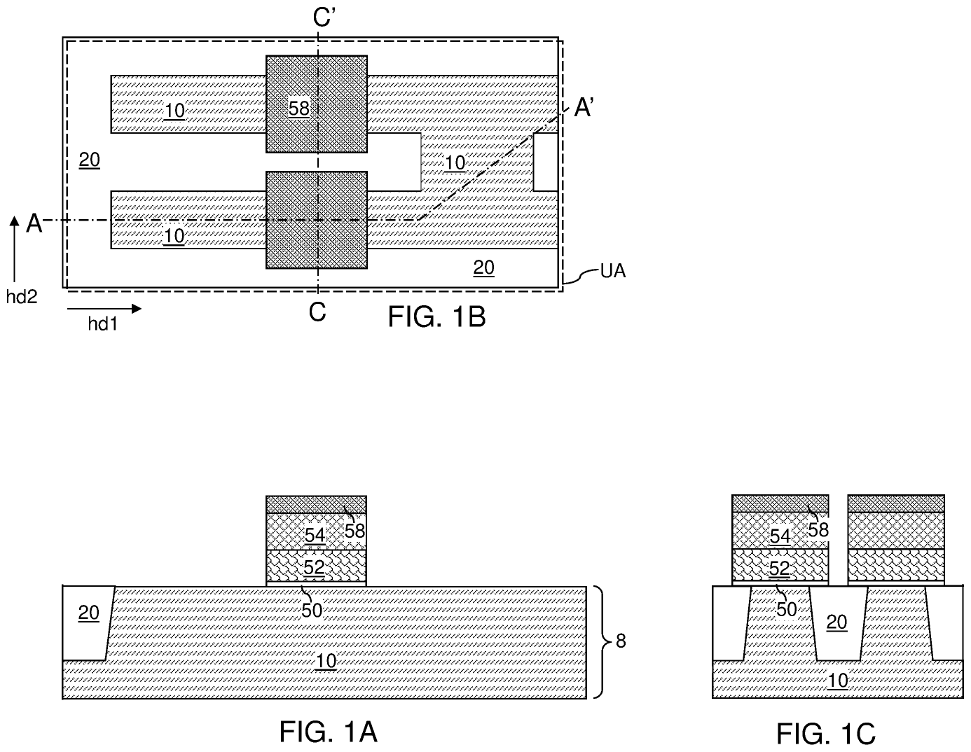

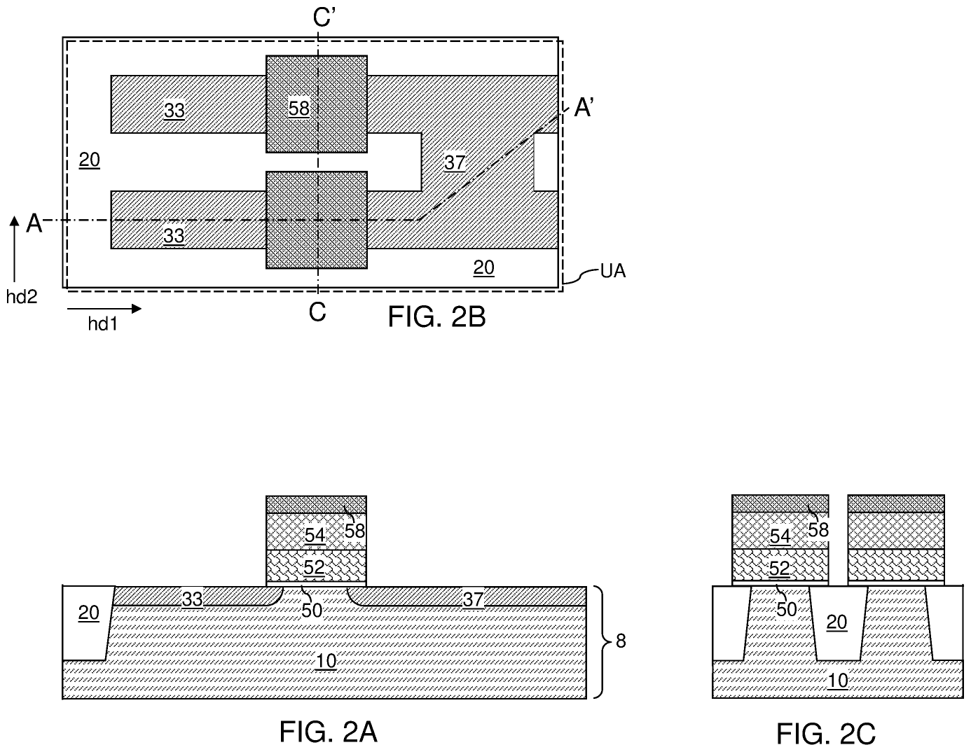

Referring to FIG. 1, an exemplary structure according to an embodiment of the present disclosure is illustrated. The exemplary structure includes a substrate 8, which may be a semiconductor substrate. As used herein, a “semiconductor substrate” refers to a substrate that includes at least one semiconductor material portion, i.e., at least one portion of a semiconductor material. In one embodiment, the substrate 8 includes a semiconductor material layer 10. The substrate 8 may optionally include at least one additional material layer at a bottom portion thereof. In one embodiment, the semiconductor substrate can be a bulk semiconductor substrate consisting of the semiconductor material layer 10, or can be a semiconductor-on-insulator (SOI) substrate including a buried insulator layer (such as a silicon oxide layer) underlying the semiconductor material layer 10, and a handle substrate underlying the buried insulator layer. In one embodiment, the substrate 8 may comprise a commercially available bulk silicon wafer or a commercially available silicon-on-insulator wafer.

The semiconductor material layer 10 can include a lightly doped semiconductor material (e.g., silicon) portion on which at least one field effect transistor can be formed. In one embodiment, the entirety of the semiconductor material in the semiconductor material layer 10 may include the lightly doped semiconductor material. In another embodiment, the lightly doped semiconductor material can be a semiconductor well embedded within another semiconductor material having a different dopant concentration and optionally, a doping of the opposite conductivity type. The dopant concentration of the lightly doped semiconductor material portion may be optimized for a body region of the at least one field effect transistor to be subsequently formed. For example, the lightly doped semiconductor material portion may include electrical dopants at an atomic concentration in a range from 1.0×10¹⁴/cm³ to 1.0×10¹⁸/cm³, such as from 1.0×10¹⁵/cm³ to 1.0×10¹⁷/cm³, although lesser and greater atomic concentrations can also be employed. The conductivity type of the portion of the semiconductor material layer 10 to be subsequently employed as a body region of a field effect transistor is herein referred to as a first conductivity type, which may be p-type for an n-type field effect transistor or n-type for a p-type field effect transistor.

The semiconductor material of the semiconductor material layer 10 can be an elemental semiconductor material (such as silicon) or an alloy of at least two elemental semiconductor materials (such as a silicon-germanium alloy), or can be a compound semiconductor material (such as a III-V compound semiconductor material or a II-VI compound semiconductor material), or can be an organic semiconductor material. The thickness of the semiconductor material layer 10 can be in a range from 0.5 mm to 2 mm in case the semiconductor material layer 10 is a bulk semiconductor substrate. In case the semiconductor material layer 10 is a semiconductor-on-insulator substrate, the thickness of the top semiconductor material layer within the semiconductor material layer 10 may be in a range from 100 nm to 1,000 nm, although lesser and greater thicknesses can also be employed.

Pad layers (not shown) such as a stack of a silicon oxide layer and a silicon nitride layer can be deposited over the top surface of the semiconductor material layer 10, and can be lithographically patterned to cover each device region, i.e., each region in which semiconductor devices are to be subsequently formed. An anisotropic etch process can be performed to etch shallow trenches that vertically extend through the pad layers and into an upper portion of the semiconductor material layer 10. The photoresist layer can be employed as an etch mask layer during the anisotropic etch process. The depth of the shallow trenches, as measured from the horizontal plane including the top surface of the semiconductor material layer 10, can be in a range from 300 nm to 3 microns, although lesser and greater depths may also be employed. The shallow trenches can be interconnected among one another to provide multiple device regions that correspond to a respective unetched portion of the semiconductor material layer 10. The photoresist layer can be subsequently removed, for example, by ashing.

In one embodiment, an array of field effect transistors can be formed over the substrate 8. In this case, the array of field effect transistors may comprise a periodic repetition of a unit device structure, formed in a respective unit area UA. The unit device structure may comprise two adjacent field effect transistors which share a common source or drain region, but which have separate gate electrodes, channels and the other one of the source or drain region. While one unit area UA is illustrated in FIGS. 1A-1C, it is understood that multiple instances of the unit area UA or a mirror image pattern thereof can be repeated as a one-dimensional periodic array or as a two-dimensional periodic array. In the illustrated example, the pattern of the unit area UA alternates with a mirror image pattern of the unit area UA along a first horizontal direction hd1. In other words, an abutting combination of a pattern of the illustrated unit area UA and a mirror image pattern of the illustrated unit area UA may function as a unit of repetition along the first horizontal direction hd1. This pattern can be repeated along the second horizontal direction hd2 to generate a pattern of a two-dimensional periodic array. In case field effect transistors are formed within portions of the semiconductor material layer 10 that are laterally surrounded by the shallow trench trenches, each portion of the semiconductor material layer 10 that is laterally surrounded by the shallow trenches may comprise an active region of a respective set of at least one field effect transistor.

At least one dielectric material, such as undoped silicate glass (i.e., silicon oxide), can be deposited in the shallow trenches by a conformal deposition process such as a chemical vapor deposition process. A chemical mechanical planarization process can be performed to remove portions of the at least one dielectric material from above the pad layers. The remaining portions of the at least one dielectric material constitute shallow trench isolation structures 20. The pad layers can be subsequently removed, for example, by wet etch processes. For example, a wet etch employing hot phosphoric acid can be performed to remove the silicon nitride layer, and a wet etch process employing dilute hydrofluoric acid can be performed to remove the silicon oxide layer. Physically exposed surfaces of the shallow trench isolation structures 20 may be collaterally recessed during removal of the silicon oxide layer.

Generally, a shallow trench isolation structure 20 comprising a dielectric material can be formed in an upper region of the semiconductor material layer 10. The semiconductor material layer can have a doping of the first conductivity type, and the shallow trench isolation structure 20 can laterally surround each device region of the semiconductor material layer 10 that is located within a respective unit area UA.

A gate dielectric layer having a thickness suitable for operation of a high voltage field effect transistor can be formed on all physically exposed surfaces of the semiconductor material layer 10, for example, by thermal oxidation of the physically exposed surface portions of the semiconductor material layer 10. If the semiconductor material layer 10 includes single crystalline silicon, the gate dielectric layer can consist essentially of thermal silicon oxide. The thickness of the gate dielectric layer can be in range from 1 nm to 50 nm, such as in a range from 6 nm to 30 nm, although lesser and greater thicknesses can also be employed.

At least one gate electrode material layer can be deposited over the gate dielectric layer. The at least one gate electrode material layer includes one or more layers of an electrically conductive material that can be employed as a gate electrode material. In an illustrative embodiment, the at least one gate electrode material layer can include a semiconductor gate electrode layer including a doped semiconductor material. For example, the semiconductor gate electrode layer can include a doped polysilicon layer having a thickness in a range from 30 nm to 150 nm. Optionally, the at least one gate electrode material layer may comprise a metallic gate electrode layer deposited on a top surface of the semiconductor gate electrode layer. The metallic gate electrode layer can include a metallic material, such as a transition metal or metal silicide and can have a thickness in a range from 50 nm to 150 nm, although lesser and greater thicknesses may also be employed.

An optional gate cap dielectric layer can be formed over the at least one gate electrode material layer. The gate cap dielectric layer comprises a gate cap dielectric material, such as silicon nitride. The thickness of the gate cap dielectric layer may be in a range from 10 nm to 50 nm, although lesser and greater thicknesses may also be employed.

In an alternative embodiment, the order of steps may be changed. For example, the shallow trench isolation structure 20 may be formed after formation of the at least one gate electrode material layer. In such an alternative embodiment, the at least one gate electrode material layer, the gate dielectric layer and the semiconductor material layer 10 may be patterned together to form the shallow trenches prior to forming the shallow trench isolation structure 20.

A photoresist layer (not shown) can be applied over the gate cap dielectric layer, and can be lithographically patterned to form gate patterns, i.e., patterns of gate electrodes to be subsequently formed. In one embodiment, the gate patterns can include two discrete photoresist material portions that laterally extend over a portion of the semiconductor material layer 10 within each unit area UA. An anisotropic etch process can be performed to transfer the gate patterns through the at least one gate electrode material layer and optionally through the gate dielectric layer. The photoresist layer can be removed, for example, by ashing. Each patterned portion of the gate dielectric layer comprises a gate dielectric 50. Each patterned portion of the at least one gate electrode material layer comprises a gate electrode (52, 54). In one embodiment, a pair of gate stack structures (50, 52, 54, 58) may be formed within each unit area UA. In one embodiment, each gate electrode (52, 54) may comprise a semiconductor gate electrode portion 52 and a metallic gate electrode portion 54. Each patterned portion of the gate cap dielectric layer constitutes a gate cap dielectric 58.

In one embodiment, each gate electrode (52, 54) may include portions that extend over the shallow trench isolation structure 20. The lateral distance between two edges of a gate electrode (52, 54) that overlie an active region of the semiconductor material layer 10 is herein referred to as a gate length, which may be in a range from 3 nm to 500 nm, although lesser and greater dimensions may also be employed. Each contiguous combination of a gate dielectric 50, a gate electrode (52, 54), and a gate cap dielectric 58 constitutes a gate stack structure (50, 52, 54, 58).

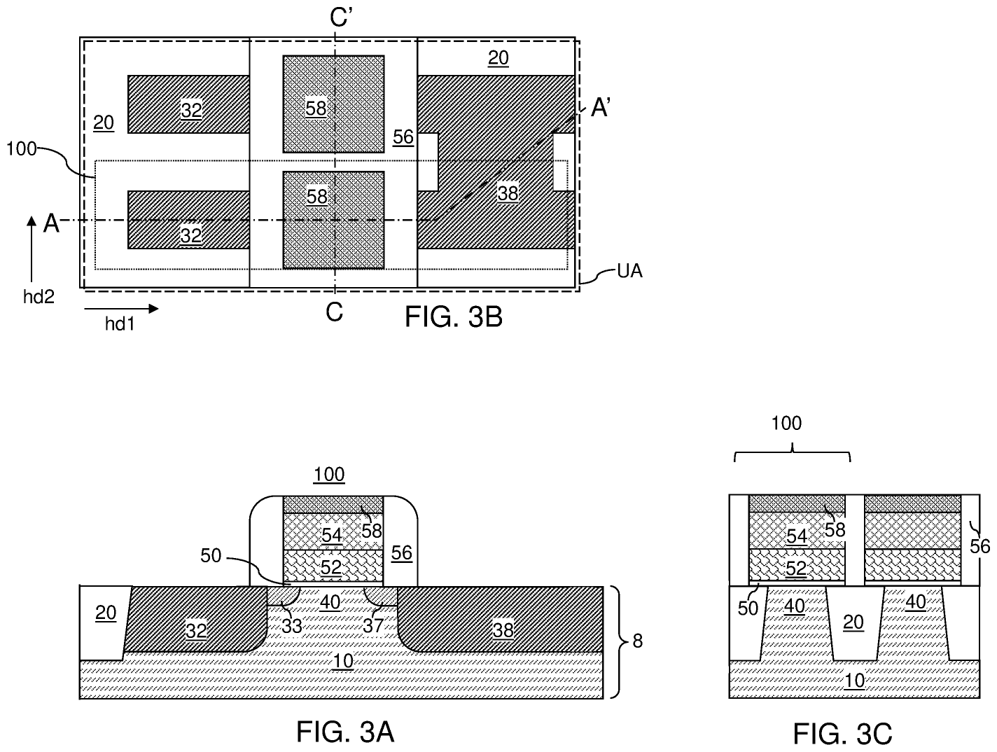

Referring to FIGS. 2A-2C, a first ion implantation process can be performed to form source/drain extension regions (33, 37), which include a source extension region 33 and a drain extension region 37. The gate stack structures (50, 52, 54, 58) are employed as an implantation mask during the first ion implantation process. Atomic concentrations of electrical dopants in the source/drain extension regions (33, 37) may be in a range from 1×10¹⁶/cm³ to 5×10¹⁸/cm³, although lesser and greater atomic concentrations may also be employed. Halo ion implantations may be optionally performed to form halo regions within the active regions underneath edges of the gate stack structures (50, 52, 54, 58). In one embodiment, the source extension region 33 and the drain extension region 37 of each field effect transistor may be laterally spaced from each other along the first horizontal direction hd1.

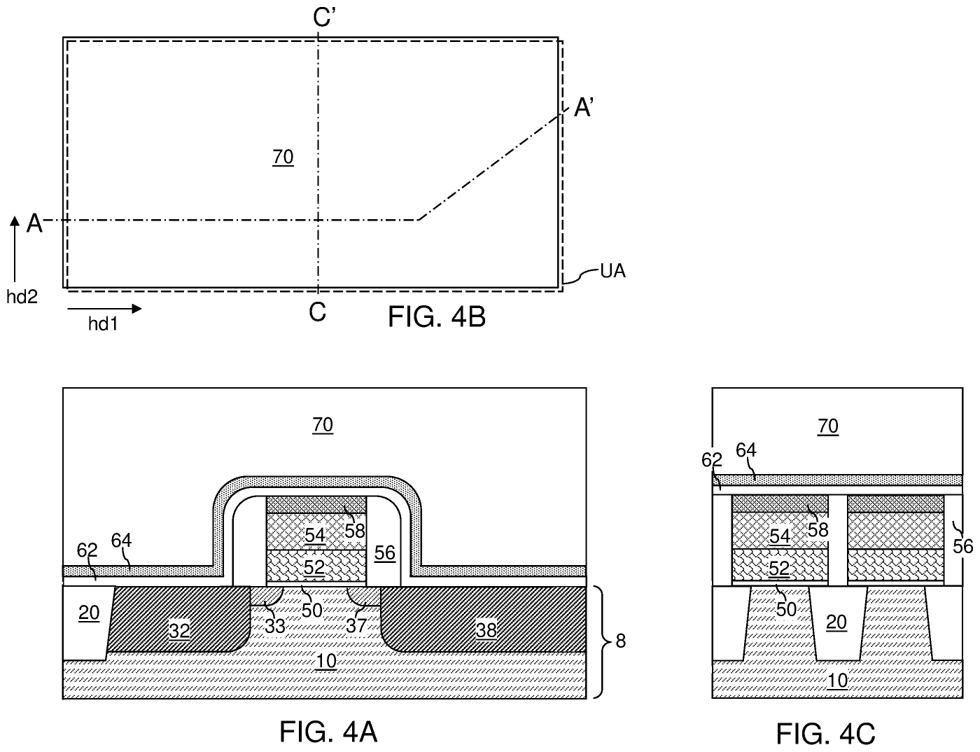

Referring to FIGS. 3A-3C, at least one conformal dielectric material layer, such as a silicon oxide or a silicon nitride layer can be deposited, for example, by a chemical vapor deposition process. The thickness of the at least one conformal dielectric material layer can be less than one half of the lateral separation distance between the pair of gate stack structures (50, 52, 54, 58) in each unit area UA. For example, the thickness of the at least one conformal dielectric material layer may be in a range from 5 nm to 300 nm, such as from 20 nm to 150 nm, although lesser and great thicknesses may also be employed.

The at least one conformal dielectric layer can be anisotropic ally etched by an anisotropic sidewall spacer etch process, such as a reactive ion etch process. Each remaining vertically-extending portion of the at least one conformal dielectric layer comprises a respective gate spacer 56. Each gate spacer 56 comprises a sidewall spacer that laterally surrounds at least one gate electrode (52, 54). The lateral thickness of each gate spacer 56 may be in a range from 5 nm to 300 nm, such as from 20 nm to 150 nm, although lesser and great thicknesses may also be employed.

A second ion implantation process can be performed to form source/drain regions (32, 38), which include a source region 32 and a drain region 38. The combination of the gate stack structures (50, 52, 54, 58) and gate spacers 56 is employed as an implantation mask during the second ion implantation process. Atomic concentrations of electrical dopants in the source/drain regions (32, 38) may be in a range from 5×10¹⁸/cm³ to 2×10²¹/cm³, although lesser and greater atomic concentrations may also be employed. Portion of the source/drain extension regions (33, 37) that are distal from the gate stack structures (50, 52, 54, 58) are incorporated into the source/drain regions (32, 38). In one embodiment, the source region 32 and the drain region 38 of each field effect transistor may be laterally spaced from each other along the first horizontal direction hd1.

An activation anneal process can be performed to electrically activate the dopants in the source/drain regions (32, 38) and the source/drain extension regions (33, 37). The peak temperature of the activation anneal process may be in a range from 800 degrees Celsius to 1,050 degrees Celsius. The duration of the peak temperature during the activation anneal process may be in a range from 1 second to 120 minutes, although lesser and greater durations may also be employed. A semiconductor channel region 40 of each respective field effect transistor 100 is located between the respective source region 32 and the respective drain region 38 below the gate stack structure (50, 52, 54, 58).

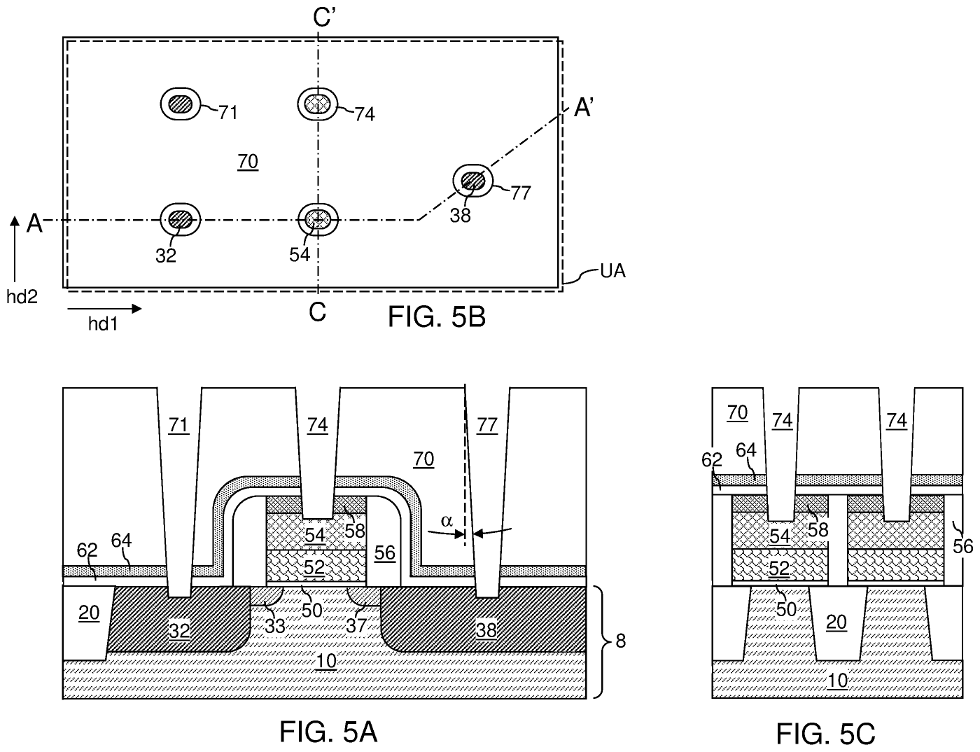

Referring to FIGS. 4A-4C, at least one dielectric liner (62, 64) can be formed over the substrate 8, the gate stack structure (50, 52, 54, 58), and the gate spacers 56. The at least one dielectric liner (62, 64) includes at least one dielectric material, such as silicon oxide, silicon nitride, silicon nitride carbide (i.e., silicon carbonitride), or a dielectric metal oxide (e.g., aluminum oxide). Each dielectric liner (62, 64) may be formed by a conformal deposition process such as a chemical vapor deposition process or an atomic layer deposition process. Each dielectric liner (62, 64) continuously extends over the metal-semiconductor alloy regions (42, 48), the gate stack structures (50, 52, 54, 58), the gate spacers 56, and the source/drain regions (32, 38). In one embodiment, the at least one dielectric liner (62, 64) may comprise a layer stack including a first dielectric liner 62 and a second dielectric liner 64. In an illustrative example, the first dielectric liner 62 comprises a silicon oxide liner, and the second dielectric liner 64 comprises a silicon nitride liner. The thickness of each dielectric liner (62, 64) may be in a range from 5 nm to 50 nm, although lesser and greater thicknesses may also be employed.

In summary, a semiconductor device comprising at least one electrical node can be formed on a substrate 8. The semiconductor device may comprise any semiconductor device known in the art, and may include a field effect transistor, a bipolar transistor, a diode, a capacitor, a resistor, an inductor, etc. In one embodiment, the semiconductor device comprises a pair of field effect transistors which share a common drain region 38 and have separate source regions 32 and separate gate electrodes (52, 54), and the at least one electrical node may comprises a source region 32 of the field effect transistor, a drain region 38 of the field effect transistor (e.g., a common drain region 38 of the pair of field effect transistors), and a gate electrode (52, 54) of the field effect transistor.

Referring to FIGS. 4A-4C, at least one dielectric liner (62, 64) can be formed over the substrate 8, the gate stack structure (50, 52, 54, 58), and the gate spacers 56. The at least one dielectric liner (62, 64) includes a dielectric material such as silicon nitride, silicon nitride carbide (i.e., silicon carbonitride), or a dielectric metal oxide (e.g., aluminum oxide). The at least one dielectric liner (62, 64) may be formed by a conformal deposition process such as a chemical vapor deposition process or an atomic layer deposition process. The at least one dielectric liner (62, 64) continuously extends over the metal-semiconductor alloy regions (42, 48), the gate stack structures (50, 52, 54, 58), the gate spacers 56, the source regions 32, and the drain regions 38. The at least one dielectric liner (62, 64) comprises vertically-extending portions that laterally surround a respective gate stack structure (50, 52, 54, 58) and a respective gate spacer 56, and horizontally-extending portions that are located over the metal-semiconductor alloy regions (42, 48). Each bottom periphery of the vertically extending portions of the at least one dielectric liner (62, 64) is adjoined to the respective adjacent horizontally-extending portions. The thickness of the at least one dielectric liner (62, 64) may be in a range from 5 nm to 50 nm, although lesser and greater thicknesses may also be employed.

A contact-level dielectric layer 70 can be deposited over the at least one dielectric liner (62, 64). The contact-level dielectric layer 70 comprises and/or consists essentially of a planarizable dielectric material (such as undoped silicate glass or a doped silicate glass) or a self-planarizing dielectric material (such as a flowable oxide). In case the contact-level dielectric layer 70 comprises a planarizable dielectric material, a planarization process (such as a chemical mechanical polishing (CMP) process) may be performed to provide a planar top surface for the contact-level dielectric layer 70. The top surface of the contact-level dielectric layer 70 can be formed above a horizontal plane including the topmost surface of the at least one dielectric liner (62, 64). A vertical distance between the top surface of the contact-level dielectric layer 70 and the horizontal plane including the topmost surface of the at least one dielectric liner (62, 64) may be in a range from 100 nm to 600 nm, such as from 150 nm to 300 nm, although lesser and greater vertical distances may also be employed.

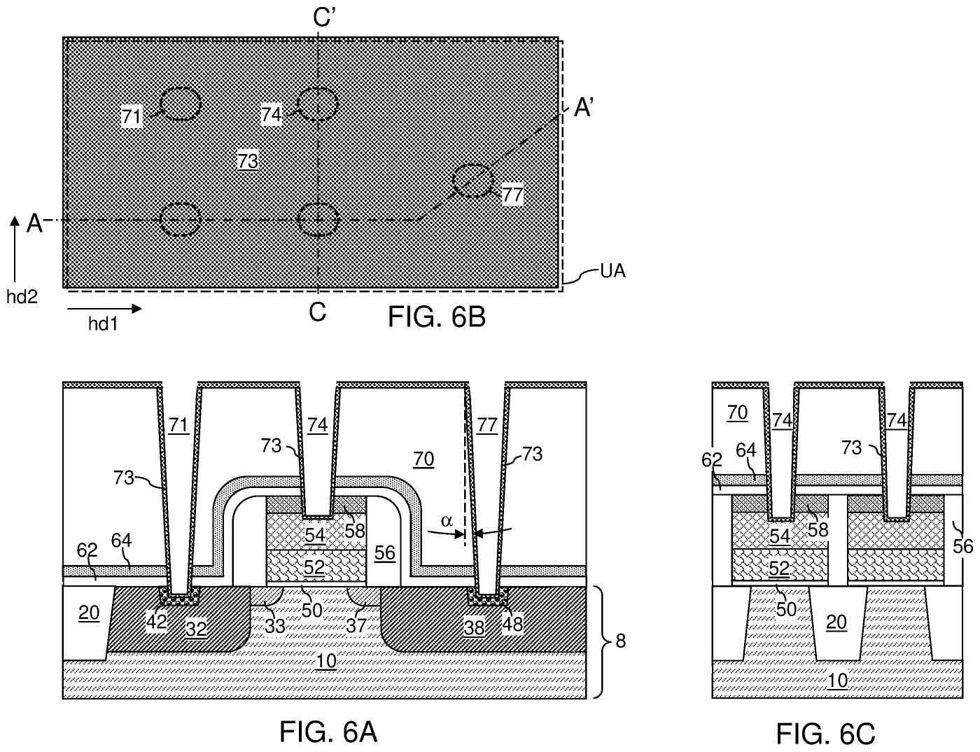

Referring to FIGS. 5A-5C, a photoresist layer (not illustrated) can be applied over the contact-level dielectric layer 70, and can be lithographically patterned to form discrete openings over areas of the electrical nodes of the underlying semiconductor devices. If the underlying semiconductor devices comprise field effect transistors, the discrete openings in the photoresist layer may be formed over areas of the source regions 32, the drain regions (e.g., common drain region of a pair of field effect transistors) 38, and the gate electrodes (52, 54) of the field effect transistors.

An anisotropic etch process can be performed to transfer the pattern of the discrete openings in the photoresist layer through the contact-level dielectric layer 70, the at least one dielectric liner (62, 64), and the gate cap dielectrics 58. Contact via cavities (71, 77, 74) vertically extending from the top surface of the contact-level dielectric layer 70 to a respective one of the electrically conductive node of the field effect transistors can be formed. The contact via cavities (71, 77, 74) may comprise source contact via cavities 71, drain contact via cavities (e.g., common drain contact cavity) 77, and gate contact via cavities 74. A top surface of a source region 32 can be exposed underneath each source contact via cavity 71. A top surface of a drain region 38 can be exposed underneath each drain contact via cavity 77. A top surface of a gate electrode (52, 54) can be exposed underneath each gate contact via cavity 74.

In one embodiment, each of the contact via cavities (71, 77, 74) may have a tapered sidewall having a taper angle α relative to a vertical direction. The taper angle α may be in a range from 0.5 degree to 8 degrees, such as from 1 degree to 6 degrees. In one embodiment, the taper angle α may be constant throughout the sidewalls of the contact via cavities (71, 77, 74). The horizontal cross-sectional area of each contact via cavity (71, 77, 74) may decrease with a downward distance from the horizontal plane including the top surface of the contact-level dielectric layer 70.

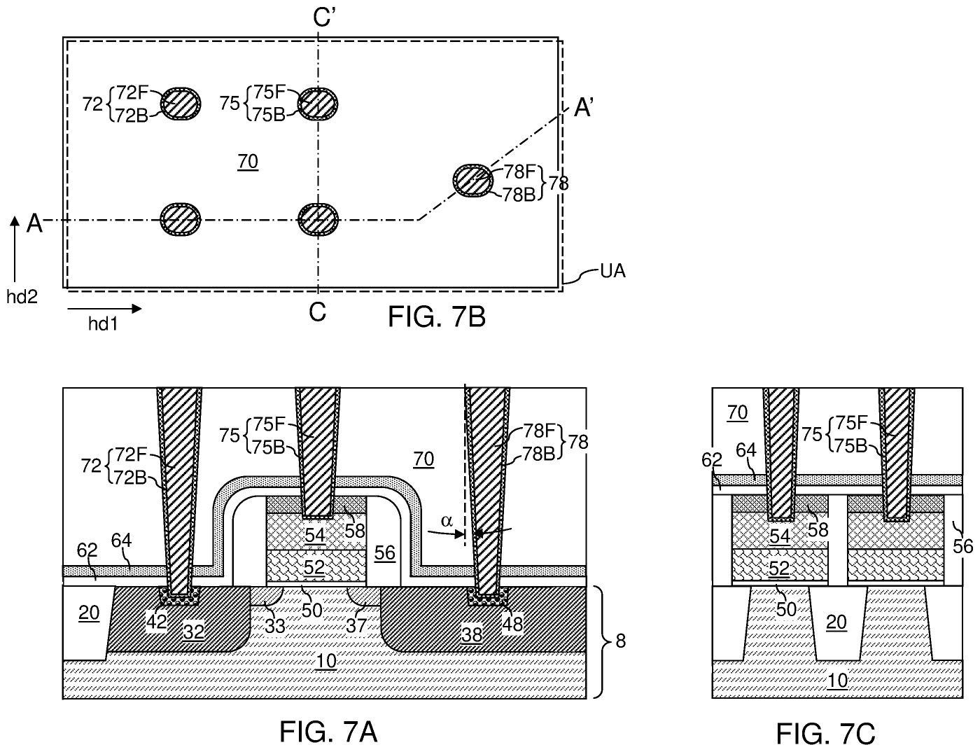

Referring to FIGS. 6A-6C, optional metal-semiconductor alloy regions (42, 48) may be subsequently formed. In this case, a metal or metal alloy layer 73 that forms a metal-semiconductor alloy with the semiconductor material of the semiconductor material layer 10 may be deposited by a conformal or non-conformal deposition process. For example, if the semiconductor material layer 10 comprises silicon, the metal or metal alloy layer may comprise a silicide-forming metal, such as titanium, tungsten, nickel, cobalt, platinum, molybdenum or alloys thereof. In an illustrative example, the metal or metal alloy layer 73 comprises a titanium layer or a combination of a titanium layer and an overlying titanium nitride layer, which also function as a diffusion barrier.

A thermal anneal process can be performed at an elevated temperature to induce a metallization reaction between the metal(s) and the semiconductor material(s) of the semiconductor material layer 10. The elevated temperature may be in a range from 500 degrees Celsius to 900 degrees Celsius depending on the material compositions of the metal or metal alloy layer and the semiconductor material(s) of the semiconductor material layer 10. The reacted portions of the metal or metal alloy layer form the metal-semiconductor alloy regions (42, 48). If the metal or metal alloy layer 73 comprises a titanium layer, the thermal anneal may be conducted in a nitrogen ambient to form titanium silicide metal-semiconductor alloy regions (42, 48) and to convert at least an exposed surface portion of the titanium layer 73 to a titanium nitride layer. Alternatively, the entire titanium layer is converted to lower titanium silicide and upper titanium nitride portions.

Unreacted portions of the metal layer 73 that do not form the metal-semiconductor alloy regions (42, 48) may be retained (e.g., if they comprise a barrier metal or metal alloy, such as Ti and/or TiN) or removed selective to the metal-semiconductor alloy regions (42, 48). The metal-semiconductor alloy regions (42, 48) may comprise a source-side metal-semiconductor alloy region 42 and a drain-side metal-semiconductor alloy region 48.

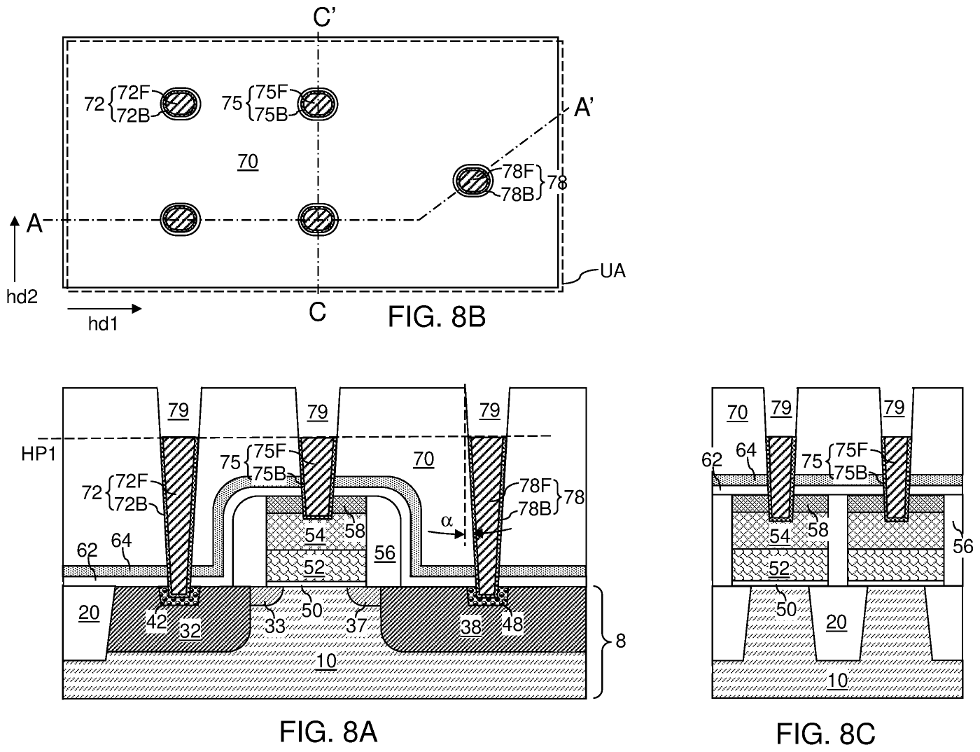

Referring to FIGS. 7A-7C, at least one first conductive material is deposited in each of the contact via cavities (71, 77, 74). If the metal or metal alloy layer 73 comprises a diffusion barrier (such as a Ti/TiN bilayer or a TiN layer), then it forms at least part of a barrier liner. Alternatively, a separate conductive metal nitride barrier liner, such as titanium nitride, tungsten nitride, tantalum nitride, molybdenum nitride, etc. may be deposited into the contact via cavities. A metal fill material, such as tungsten, tantalum, titanium, molybdenum, cobalt, ruthenium, etc., the subsequently deposited into the contact via cavities over the barrier liner.

Optionally, excess portions of the at least one first conductive material can be removed from above the horizontal plane including the top surface of the contact-level dielectric layer 70 by performing a planarization process, such as a chemical mechanical polishing (CMP) process. Each remaining portion of the at least one first conductive material that fills a respective one of the contact via cavities (71, 77, 74) constitutes a contact via structure (72, 78, 75). The contact via structures (72, 78, 75) formed within a unit area UA may comprise source contact via structures 72, a drain contact via structure 78, and gate contact via structures 75. Each source contact via structure 72 may comprise a source-side metallic barrier liner (e.g., a Ti/TiN bilayer or a TiN liner) 72B and a source-side via fill metal portion (e.g., W) 72F. The drain contact via structure 78 may comprise a drain-side metallic barrier liner 78B and a drain-side via fill metal portion 78F. Each gate contact via structure 75 may comprise a gate-side metallic barrier liner 75B and a gate-side via fill metal portion 75F. Optionally, top surfaces of the contact via structures (72, 78, 75) may be formed within the horizontal plane including the top surface of the contact-level dielectric layer 70. The bottom surface of each source contact via structure 72 may contact a source-side metal-semiconductor alloy region 42 or a source region 32. Alternatively, the planarization process may be omitted. The bottom surface of each drain contact via structure 78 may contact a drain-side metal-semiconductor alloy region 48 or a drain region 38. The bottom surface of each gate contact via structure 75 may contact a gate electrode (52, 54).

Generally, each contact via structure (72, 78, or 75) vertically extends through the contact-level dielectric layer 70 and contacts a respective one of the at least one electrical node {(32, 42), (38, 48), (52, 54)} of an underlying semiconductor device. In one embodiment, each contact via structure (72, 78, or 75) may comprise a sidewall having a non-zero taper angle α with respect to a vertical direction throughout the contact-level dielectric layer 70 and contacting a respective electrical node {(32, 42), (38, 48), (52, 54)} of an underlying semiconductor device.

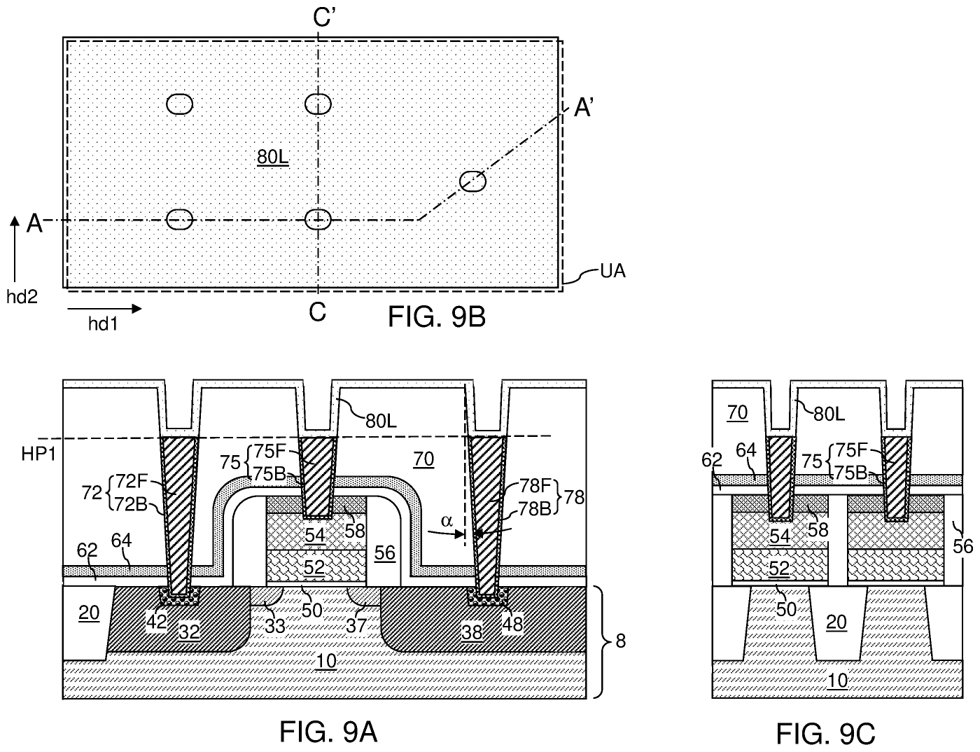

Referring to FIGS. 8A-8C, a selective recess etch process can be performed to vertically recess the contact via structures (72, 78, 75). The selective recess etch process etches the materials of the contact via structures (72, 78, 75) selective to the dielectric material of the contact-level dielectric layer 70. The selective recess etch process may comprise a wet etch process or a reactive ion etch process. For example, if the contact-level dielectric layer 70 comprises silicon oxide and if the contact via structures (72, 78, 75) comprise a combination of Ti, TiN and W, exemplary selective recess etch processes that may be employed to vertically recess the top surfaces of the contact via structures (72, 78, 75) include a wet etch process employing a mixture of hydrogen peroxide (H₂O₂) and ammonium hydroxide (NH₄OH); a wet etch process employing hydrogen peroxide and sulfuric acid; and a reactive ion etch process employing a fluorine-based etch chemistry or a chlorine-based etch chemistry (employing Cl₂/Ar, Cl₂/N₂, or Cl₂/Ar/N₂), etc.

The selective recess etch process vertically recesses an upper portion of each contact via structure (72, 78, or 75) below the top surface of the contact-level dielectric layer 70. Thus, the above described planarization process shown in FIGS. 7A-7C may be either performed prior to the selective etch process or omitted. Recessed top surface of the contact via structures (72, 78, 75) can be formed formed within a first horizontal plane HP1 that is located between the horizontal plane including the top surface of the contact-level dielectric layer 70 and a horizontal plane including the topmost surface of the at least one dielectric liner (62, 64). The vertical distance between the first horizontal plane HP1 and the horizontal plane including the top surface of the contact-level dielectric layer 70 may be in a range from 15% to 70%, such as from 30% to 50%, of the vertical distance between the horizontal plane including the topmost surface of the at least one dielectric liner (62, 64) and the horizontal plane including the top surface of the contact-level dielectric layer 70. A recess cavity 79 can be formed above the recessed top surface of each contact via structure (72, 78, or 75).

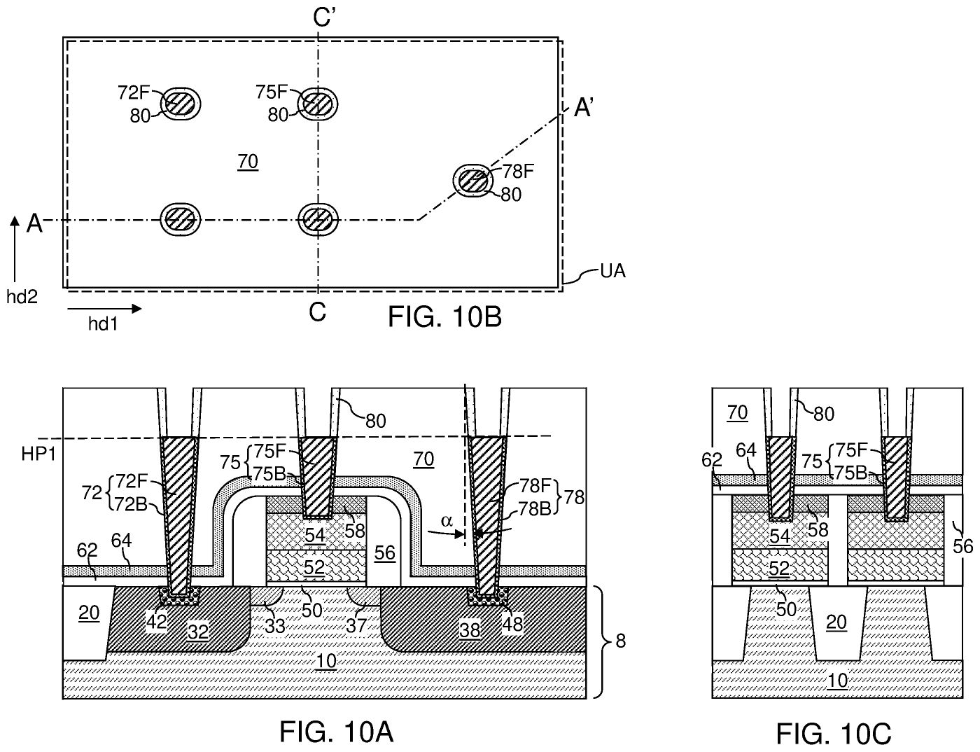

Referring to FIGS. 9A-9C, an insulating spacer material layer 80L can be conformally deposited over the contact-level dielectric layer 70 and in the recess cavities 79. The insulating spacer material layer 80L comprises an insulating material, such as undoped silicate glass (i.e., silicon oxide), a doped silicate glass, porous or non-porous organosilicate glass, silicon nitride, silicon carbonitride, or a dielectric metal oxide material. The insulating spacer material layer 80L may comprise a different material than the material of the contact-level dielectric layer 70, or may comprise a same material as the material of the contact-level dielectric layer 70. The insulating spacer material layer 80L may be deposited by a conformal deposition process such as a chemical vapor deposition process or an atomic layer deposition process. The thickness of the insulating spacer material layer 80L may be in a range from 1 nm to 30 nm, such as from 3 nm to 10 nm, although lesser and greater thicknesses may also be employed. A void that is not filled with the insulating spacer material layer 80L is present within each recess cavity 79.

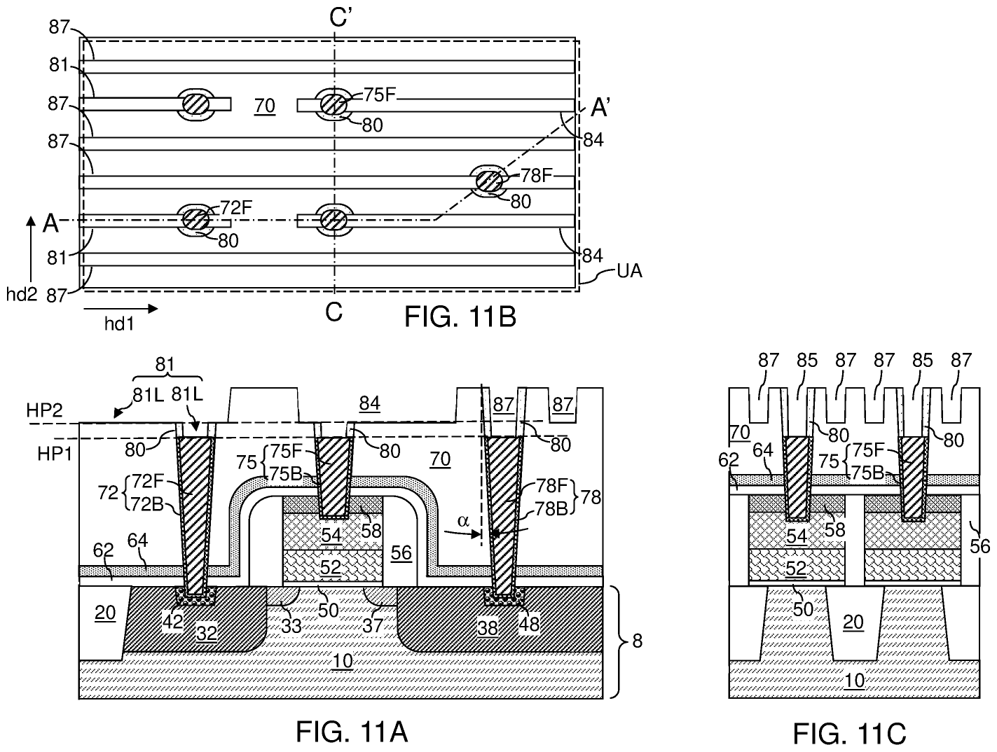

Referring to FIGS. 10A-10C, an optional anisotropic etch process can be performed to etch horizontally-extending portions of the insulating spacer material layer 80L. Each remaining portion of the insulating spacer material layer 80L within a volume of a respective recess cavity 79 constitutes an insulating spacer 80. Each insulating spacer 80 can be formed in a peripheral portion of a respective recess cavity 79. Each insulating spacer 80 may have a tapered tubular configuration, i.e., a tubular configuration in which the horizontal cross-sectional area of an opening therein increases gradually with a vertical distance from the substrate 8. In one embodiment, each insulating spacer 80 may have an annular bottom surface that is formed within the first horizontal plane HP1.

Each insulating spacer 80 may have a tapered outer sidewall having the taper angle α of 0.1 to 10 degrees. The tapered outside sidewall of each insulating spacer 80 may be located on a sidewall of a respective contact via cavity (71, 77, 74) having the taper angle α with respective to the vertical direction and vertically extending from the top surface of the contact-level dielectric layer 70 to a top surface of a respective conductive element in an underlying semiconductor device. A center segment of a top surface of an underlying contact via structure (72, 78, 75) can be physically exposed within each void that is laterally surrounded by an insulating spacer 80. The insulating spacers 80 may have a uniform lateral thickness throughout. Thus, the bottom periphery of an inner sidewall of each insulating spacer 80 can be laterally offset inward from the bottom periphery of an outer sidewall of the respective insulating spacer 80 by a uniform lateral offset distance, which can be the same as the lateral thickness of the insulating spacer 80. The lateral thickness of the insulating spacer 80 may be in a range from 1 nm to 30 nm, such as from 3 nm to 10 nm, although lesser and greater lateral thicknesses may also be employed. Alternatively, the above anisotropic etch process may be performed concurrently with the step described below.

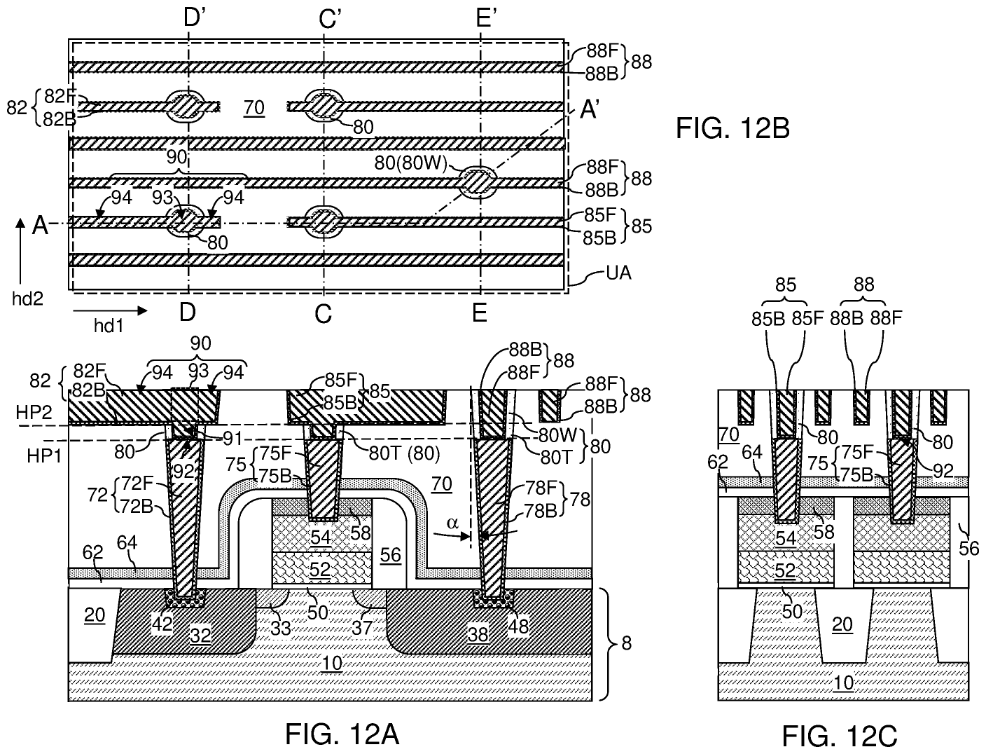

Referring to FIGS. 11A-11C, a photoresist layer (not shown) can be applied over the contact-level dielectric layer 70, and can be lithographically patterned to form line-shaped discrete openings that laterally extend along the first horizontal direction hd1. In one embodiment, a predominant fraction (i.e., more than 50%) and/or each of the line-shaped discrete openings may be formed on a respective subset of the contact via structures (72, 78, 75), i.e., in a manner that provides an areal overlap with the respective subset of the contact via structures (72, 78, 75). In one embodiment, the width of the line-shaped discrete openings along the second horizontal direction hd2 may be less than the maximum lateral dimension of a respective underlying insulating spacer 80 along the second horizontal direction hd2. In one embodiment, a pair of lengthwise edges of a line-shaped discrete opening in the photoresist layer may overlie a respective underlying insulating spacer 80.

An anisotropic etch process can be performed to transfer the pattern of the line-shaped discrete openings in the photoresist layer through the combination of the contact-level dielectric layer 70 and the insulating spacers 80 or the insulating spacer material layer 80L, whichever one is present.

If the insulating spacer material layer 80L is present, then the anisotropic etch process patterns the insulating spacer material layer 80L into the insulating spacers 80. The depths of the line-shaped discrete openings extend to the first horizontal plane HP1. Alternatively, if the insulating spacers 80 are present at this step, then the depths of the line-shaped discrete openings extend to a second horizontal plane HP2. The second horizontal plane HP2 may be located at the same height as or above the first horizonal plane HP1. If the second horizontal plane HP2 is located above the first horizonal plane HP1, then the vertical distance between the first horizontal plane HP1 and the second horizontal plane HP2 may be in a range from 5% to 70%, such as from 10% to 40%, of the vertical distance between the first horizontal plane HP1 and the horizontal plane including the top surface of the contact-level dielectric layer 70. The chemistry of the anisotropic etch process can be selected such that the anisotropic etch process etches the materials of the contact-level dielectric layer 70 and the insulating spacers 80 selective to the materials of the contact via structures (72, 78, 75). Portions of the contact-level dielectric layer 70 and the insulating spacers 80 that underlie the line-shaped openings in the photoresist layer and overlie the second horizontal plane HP2 are removed by the anisotropic etch process.

Line cavities (81, 87, 84) are formed in the volumes from which the materials of the contact-level dielectric layer 70 and the insulating spacers 80 (or layer 80L) are removed. Further, portions of the voids within the volumes of the recess cavities 79 that are not filled with the insulating spacers 80 are incorporated into the line cavities (81, 87, 84). As such, each line cavity (81, 87, 84) comprises a horizontally-extending line-shaped cavity portion (e.g., 81L) that overlies the second horizontal plane HP2 and at least one pillar-shaped cavity portion (e.g., 81P) that underlies the second horizontal plane HP2 and adjoined to the horizontally-extending line-shaped cavity portion (e.g., 81L). The line cavities (81, 87, 84) comprise source line cavities 81 that are formed above a respective subset of the source contact via structures 72, drain line cavities 87 that are formed above a respective subset of the drain contact via structures 78, and gate line cavities 84 that are formed above a respective subset of the gate contact via structures 75.

In one embodiment, the line cavities (81, 87, 84) may have a modified line-and-space pattern which is modified from a line-and-space pattern by disconnecting a subset of the line patterns. As used herein, a line-and-space pattern refers to a pattern including a one-dimensional periodic array in which a unit pattern is repeated with a periodicity along a repetition direction. The unit pattern consists of a pattern of a first elongated rectangle laterally extending along a horizontal lengthwise direction and having a uniform line width and a pattern of a second elongated rectangle that abuts a lengthwise sidewall of the straight line, laterally extends along the horizontal lengthwise direction, and has a uniform space width. A structure or a cavity is present within each pattern of the first elongated rectangle, and is absent within each pattern of the second elongated rectangle. The repetition direction is perpendicular to the horizontal lengthwise direction. The sum of the uniform line width and the uniform space width equals the periodicity.

The line cavities (81, 87, 84) can be formed such that the line cavities (81, 87, 84) are formed within, but does not occupy the entirety of, the areas of the patterns of the first elongated rectangles. The first horizontal direction hd1 can be the elongation direction of the line cavities (81, 87, 84), and the second horizontal direction hd2 can be pattern repetition direction. The line cavities (81, 87, 84) are not present within the areas of the patterns of the second elongated rectangles. The deviation of the pattern of the line cavities (81, 87 84) from the line-and-space pattern is due to the absence of the line cavities (81, 87, 84) within a fraction of the areas of the patterns of the first elongated rectangles. Specifically, cut regions are present in the pattern of the line cavities (81, 87, 84) such that at least some of the line cavities (81, 87, 84) have lateral extents along the first horizontal direction that is less than the full length of the pattern of the line cavities (81, 87, 84) along the first horizontal direction hd1. For example, a cut region may be provided for each of the gate line cavities 84 within each unit area UA. Generally, different types of cut regions may be employed depending on the electrical connection scheme that is employed to wire the underlying semiconductor device.

In summary, a line cavity (81, 87, 84) can be formed in an upper portion of the contact-level dielectric layer 70 over a semiconductor device by forming a patterned etch mask layer (such as a patterned photoresist layer) over the contact-level dielectric layer 70 and by performing an anisotropic etch process. Each portion of a recess cavity 79 that is not filled within the insulating spacer 80 may be incorporated into a respective line cavity (81, 87, 84). In one embodiment, a bottom surface of each line cavity (81, 87, 84) may be formed within a second horizontal plane HP2 that overlies the first horizontal plane HP1.

In one embodiment in which the insulating spacers 80 are formed in a separate etch shown in FIGS. 10A-10C, the insulating spacer 80 may comprise a tubular portion that is located below the second horizontal plane HP2 and a pair of wing portions that protrude above the second horizontal plane HP2 and having sidewall surfaces that are exposed to a line cavity (81, 87, 84). In another embodiment in which the insulating spacers 80 are formed at the same etching step as line cavities (81, 87, 84) in FIGS. 11A-11C, the insulating spacer 80 may comprise a pair of wing portions that protrude above the second horizontal plane HP2 and having sidewall surfaces that are exposed to a line cavity (81, 87, 84)

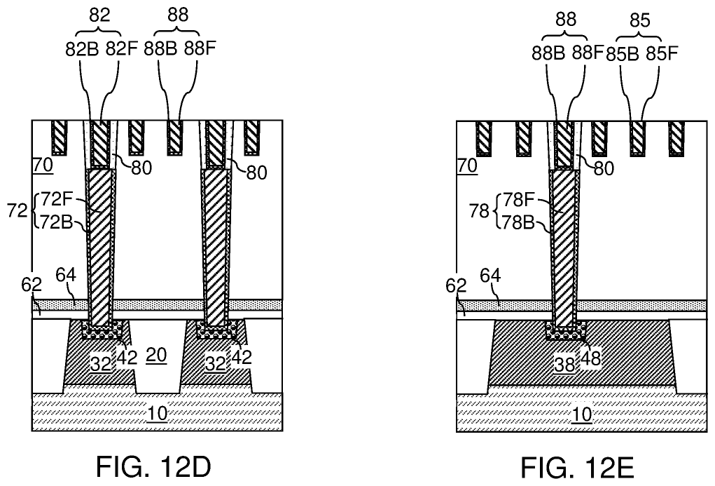

Referring to FIGS. 12A-12E, at least one second conductive material, can be deposited in each of the line cavities (81, 87, 84). The at least one second conductive material may comprise, for example, a metallic barrier liner including a conductive metal nitride material and a metal fill material. The conductive metal nitride material may comprise titanium nitride, tungsten nitride, tantalum nitride, molybdenum nitride, etc. The metal fill material may comprise tungsten, tantalum, titanium, molybdenum, cobalt, ruthenium, copper, etc.

Excess portions of the at least one second conductive material can be removed from above the horizontal plane including the top surface of the contact-level dielectric layer 70 by performing a planarization process such as a chemical mechanical polishing (CMP) process. Each remaining portion of the at least one second conductive material that fills a respective one of the line cavities (81, 87, 84) constitutes a metal line structure (82, 88, 85). The metal line structures (82, 88, 85) formed within a unit area UA may comprise source metal line structures 82, drain metal line structures 88, and gate metal line structures 85. Each source metal line structure 82 may comprise a source-line metallic barrier liner 82B and a source-line fill metal portion 82F. The drain metal line structure 88 may comprise a drain-line metallic barrier liner 88B and a drain-line fill metal portion 88F. Each gate metal line structure 85 may comprise a gate-line metallic barrier liner 85B and a gate-line fill metal portion 85F. Top surfaces of the metal line structures (82, 88, 85) may be formed within the horizontal plane including the top surface of the contact-level dielectric layer 70. Each source metal line structure 82 may contact at least one source contact via structure 72. Each drain metal line structure 88 may contact at least one drain contact via structure 78. Each gate metal line structure 85 may contact at least one gate contact via structure 75.

Each metal line structure (82, 88, or 85) can be formed in a respective line cavity (81, 87, or 84) directly on at least one recessed top surface of at least one contact via structure (72, 78, or 75). Each metal line structure (82, 88, or 85) may comprise a horizontally-extending metal line portion located above the second horizontal plane HP2 and a downward-protruding pillar portion that protrudes downward from a bottom surface of the horizontally-extending metal line portion below the second horizontal plane HP1.

According to various embodiments of the present disclosure, a device structure comprises a semiconductor device (e.g., at least one field effect transistor 100) and comprising an electrical node {(32, 42), (38, 48) and/or (52, 54)}; a contact-level dielectric layer 70 overlying the semiconductor device 100; a contact via structure (72, 78, or 75) vertically extending through a lower portion of the contact-level dielectric layer 70 and contacting the electrical node {(32, 42), (38, 48) or (52, 54)}; and a metal line structure (82, 88, or 85) laterally extending along a first horizontal direction hd1 and embedded within an upper portion of the contact-level dielectric layer 70. As shown in FIG. 12A, the metal line structure (82, 88, or 85) comprises a horizontally-extending metal line portion 90 (which may have a uniform height) and a downward-protruding pillar portion 91 that protrudes downward below bottom surface of the horizontally-extending metal line portion 90 and contacts a first (e.g., inner) segment of a top surface 92 of the contact via structure (72, 78, or 75). An insulating spacer 80 contacts a sidewall of the downward-protruding pillar portion 91 and second (e.g., outer) segment of the top surface 92 of the contact via structure (72, 78, or 75)

In one embodiment, a bottom periphery of the downward-protruding pillar portion 91 is laterally offset inward from a periphery of the top surface 92 of the contact via structure (72, 78, or 75), and a bottom periphery of the insulating spacer 80 is vertically coincident with the periphery of the top surface 92 of the contact via structure (72, 78, or 75). In one embodiment, a lateral offset distance between the bottom periphery of the downward-protruding pillar portion 91 and the periphery of the top surface of the contact via structure (72, 78, or 75) is uniform for each point within the bottom periphery of the downward-protruding pillar portion 91.

In one embodiment, the downward-protruding pillar portion 91 is laterally surrounded by a tubular portion 80T of an insulating spacer 80. In one embodiment, the contact via structure (72, 78, or 75) has a sidewall having non-zero taper angle α with respect to a vertical direction; and the tubular portion of the insulating spacer 80 comprises an outer sidewall having the taper angle α. In one embodiment, the tubular portion 80T of the insulating spacer 80 comprises a pair of top surface segments that are laterally spaced from each other along the first horizontal direction hd1 and contacting a respective surface segment of a bottom surface of the horizontally-extending metal line portion.

In one embodiment, the insulating spacer 80 further comprises a pair of wing portions 80W that protrude above a horizontal plane including a bottom surface of the horizontally-extending metal line portion 90. In one embodiment, the pair of wing portions 80W of the insulating spacer 80 contact two sidewall segments of the horizontally-extending metal line portion 90 that are parallel to the first horizontal direction hd1. In one embodiment, the pair of wing portions 80W comprise a pair of top surfaces located within a horizontal plane including a top surface of the horizontally-extending metal line portion. In one embodiment, a top surface of the contact-level dielectric layer 70 is located within the horizontal plane including the top surface of the horizontally-extending metal line portion 90.

In one embodiment, the downward-protruding pillar portion 91 and the contact via structure (72, 78, or 75) are located entirely within a contact via cavity (71, 77, or 74); and a first vertical cross-sectional profile of the contact via cavity (71, 77, or 74) along a vertical plane that is parallel to the first horizontal direction hd1 (as illustrated in FIG. 12A) comprises a pair of first straight sidewall segments that vertically extend from the electrical node {(32, 42), (38, 48) or (52, 54)} to a bottom surface of the horizontally-extending metal line portion 90. In one embodiment, a second vertical cross-sectional profile of the contact via cavity (71, 77, or 74) along a vertical plane that is perpendicular to the first horizontal direction hd1 (as illustrated in FIGS. 12C, 12D, and 12E) comprises a pair of second straight sidewall segments that vertically extend from the electrical node {(32, 42), (38, 48) or (52, 54)} to a horizontal plane including a top surface of the contact-level dielectric layer 70.

In one embodiment, a first segment 93 of the horizontally-extending metal line portion 90 that overlies the contact via structure (72, 78, or 75) and is connected to the downward-protruding pillar portion 91 is wider along the second horizontal direction hd2 than the remaining second segments 94 of the horizontally-extending metal line portion 90 that do not overlie the contact via structure (72, 78, or 75) and are not connected to the downward-protruding pillar portion 91. The first segment 93 of the horizontally-extending metal line portion 90 is laterally spaced from the contact-level dielectric layer 70 by the pair of wing portions 80W of the insulating spacer 80; and the second segments 94 of the horizontally-extending metal line portion 90 that do not have an areal overlap with the contact via structure (72, 78, or 75) in a plan view comprises a pair of sidewall surface segments that in contact with the contact-level dielectric layer 70.

In one embodiment, the top surface of the contact via structure (72, 78, or 75) has a greater lateral extent along a second horizontal direction hd2 that is perpendicular to the first horizontal direction hd1 than a lateral extent of a top surface of second segments 94 of the metal line structure (82, 88, or 85) along the second horizontal direction hd2.

In one embodiment, the semiconductor device 100 comprises a field effect transistor; and the electrical node {(32, 42), (38, 48), (52, 54)} comprises a source region 32 of the field effect transistor, a drain region 38 of the field effect transistor, or a gate electrode (52, 54) of the field effect transistor. In one embodiment, the first horizontal direction hd1 is a lateral separation direction between the source region 32 and the drain region 38; the electrical node {(32, 42), (38, 48), (52, 54)} comprises the drain region 38; and the metal line structure (82, 88, or 85) comprises a drain metal line structure 88 and has an areal overlap with the source region 32 and with the gate electrode (52, 54) in a plan view. In one embodiment, the first horizontal direction hd1 is a lateral separation direction between the source region 32 and the drain region 38; the electrical node {(32, 42), (38, 48), (52, 54)} comprises the gate electrode (52, 54); and the metal line structure (82, 88, or 85) comprises a gate metal line structure 85 and has an areal overlap with the drain region 38 in a plan view, and does not have an areal overlap with the source region 32 in the plan view.

A first segment of the horizontally-extending portion of a metal line structure contacts a respective downward-protruding pillar portions of the same metal line structure. The downward-protruding pillar portion is wider than the second segment of the horizontally-extending portion of the same metal line structure. Thus, the downward-protruding pillar portion laterally bulges out toward adjacent metal line structures. The insulating spacers 80 laterally separate and electrically isolate the relatively wide downward-protruding pillar portion and the first segment of the metal line structure from the narrower adjacent second segments of the metal line structures to reduce electrical short circuits and time-dependent dielectric breakdown (TDDB) between them. In contrast, the second segments horizontally-extending portions of adjacent metal line structures are relatively narrow and are sufficiently laterally separated and insulated from each other by the contact-level dielectric layer 70.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A device structure, comprising:
a semiconductor device comprising at least one electrical node;
a contact-level dielectric layer overlying the semiconductor device;
a contact via structure vertically extending through a lower portion of the contact-level dielectric layer and contacting one of the at least one electrical node;
a metal line structure laterally extending along a first horizontal direction and embedded within an upper portion of the contact-level dielectric layer, wherein the metal line structure comprises a horizontally-extending metal line portion and a downward-protruding pillar portion that protrudes downward below a bottom surface of the horizontally-extending metal line portion and contacts a first segment of a top surface of the contact via structure; and
an insulating spacer which contacts a sidewall of the downward-protruding pillar portion and second segment of the top surface of the contact via structure.

2. The device structure of claim 1, wherein a bottom periphery of the downward-protruding pillar portion is laterally offset inward from a periphery of the top surface of the contact via structure, and a bottom periphery of the insulating spacer is vertically coincident with the periphery of the top surface of the contact via structure.

3. The device structure of claim 2, wherein a lateral offset distance between the bottom periphery of the downward-protruding pillar portion and the periphery of the top surface of the contact via structure is uniform for each point within the bottom periphery of the downward-protruding pillar portion.

4. The device structure of claim 1, wherein
a first segment of the horizontally-extending metal line portion that overlies the contact via structure and is connected to the downward-protruding pillar portion is wider along the second horizontal direction that is perpendicular to the first horizontal direction than remaining second segments of the horizontally-extending metal line portion that do not overlie the contact via structure and are not connected to the downward-protruding pillar portion; and
the downward-protruding pillar portion is laterally surrounded by a tubular portion of the insulating spacer.

5. The device structure of claim 4, wherein:
the contact via structure has a sidewall having a non-zero taper angle with respect to a vertical direction; and
the tubular portion of the insulating spacer comprises an outer sidewall having the taper angle.

6. The device structure of claim 4, wherein the tubular portion of the insulating spacer comprises a pair of top surface segments that are laterally spaced from each other along the first horizontal direction and contacting a respective surface segment of a bottom surface of the horizontally-extending metal line portion.

7. The device structure of claim 4, wherein the insulating spacer further comprises a pair of wing portions that protrude above a horizontal plane including a bottom surface of the horizontally-extending metal line portion.

8. The device structure of claim 7, wherein the pair of wing portions of the insulating spacer contact two sidewall segments of the horizontally-extending metal line portion that are parallel to the first horizontal direction.

9. The device structure of claim 7, wherein the pair of wing portions comprise a pair of top surfaces located within a horizontal plane including a top surface of the horizontally-extending metal line portion.

10. The device structure of claim 9, wherein a top surface of the contact-level dielectric layer is located within the horizontal plane including the top surface of the horizontally-extending metal line portion.

11. The device of claim 4, wherein:
the downward-protruding pillar portion and the contact via structure are located entirely within a contact via cavity; and
a first vertical cross-sectional profile of the contact via cavity along a vertical plane that is parallel to the first horizontal direction comprises a pair of first straight sidewall segments that vertically extend from the electrical node to a bottom surface of the horizontally-extending metal line portion.

12. The device of claim 11, wherein a second vertical cross-sectional profile of the contact via cavity along a vertical plane that is perpendicular to the first horizontal direction comprises a pair of second straight sidewall segments that vertically extend from the electrical node to a horizontal plane including a top surface of the contact-level dielectric layer.

13. The device of claim 7, wherein:
the first segment of the horizontally-extending metal line portion is laterally spaced from the contact-level dielectric layer by the pair of wing portions of the insulating spacer; and
the second segments of the horizontally-extending metal line portion that do not have an areal overlap with the contact via structure in a plan view comprise a pair of sidewall surface segments that in contact with the contact-level dielectric layer.

14. The device of claim 13, wherein the top surface of the contact via structure has a greater lateral extent along a second horizontal direction that is perpendicular to the first horizontal direction than a lateral extent of a top surface of the second segments of the horizontally-extending metal line portion along the second horizontal direction.

15. The device of claim 1, wherein:
the semiconductor device comprises a field effect transistor; and
the electrical node comprises a source region of the field effect transistor, a drain region of the field effect transistor, or a gate electrode of the field effect transistor.

16. The device of claim 15, wherein:
the first horizontal direction is a lateral separation direction between the source region and the drain region;
the electrical node comprises the drain region; and
the metal line structure comprises a drain metal line structure that has an areal overlap with the source region and with the gate electrode in a plan view.

17. The device of claim 15, wherein:
the first horizontal direction is a lateral separation direction between the source region and the drain region;
the electrical node comprises the gate electrode; and
the metal line structure comprises a gate metal line structure that has an areal overlap with the drain region in a plan view, and does not have an areal overlap with the source region in the plan view.

18. A method of forming a device structure, comprising:
forming a semiconductor device comprising an electrical node;
forming a contact-level dielectric layer over the semiconductor device;
forming a contact via structure vertically extending through the contact-level dielectric layer and contacting the electrical node;
vertically recessing an upper portion of the contact via structure, wherein a recessed top surface of the contact via structure is formed within a first horizontal plane, and a recess cavity is formed above the contact via structure;
forming an insulating spacer in a peripheral portion of the recess cavity;
forming a line cavity in an upper portion of the contact-level dielectric layer by forming a patterned etch mask layer over the contact-level dielectric layer and by performing an anisotropic etch process, wherein a portion of the recess cavity that is not filled within the insulating spacer is incorporated into the line cavity; and
forming a metal line structure in the line cavity directly on the recessed top surface of the contact via structure.

19. The method of claim 18, wherein:
a bottom surface of the line cavity is formed within a second horizontal plane that overlies the first horizontal plane; and
the metal line structure comprises a horizontally-extending metal line portion located above the second horizontal plane and a downward-protruding pillar portion that protrudes downward from a bottom surface of the horizontally-extending metal line portion below the second horizontal plane.

20. The method of claim 19, wherein the insulating spacer comprises a tubular portion that laterally surrounds the downward-protruding pillar portion and a pair of wing portions that protrude above the second horizontal plane and contact a pair of sidewalls of the horizontally-extending metal portion.
